(19) United States
(12) Patent Application Publication
(10) Pub. No.: US 2013/0093490 A1
(43) Pub. Date: Apr. 18, 2013

(54) INTERNAL VOLTAGE GENERATION CIRCUIT AND METHOD

(71) Applicants: Hyun Seok KIM, Icheon-si Gyeonggi-do (KR); Ic Su OH, Icheon-si Gyeonggi-do (KR); Jun Ho LEE, Icheon-si Gyeonggi-do (KR); Boo Ho JUNG, Icheon-si Gyeonggi-do (KR); Sun Ki CHO, Icheon-si Gyeonggi-do (KR); Yang Hee KIM, Icheon-si Gyeonggi-do (KR)

(72) Inventors: Hyun Seok KIM, Icheon-si Gyeonggi-do (KR); Ic Su OH, Icheon-si Gyeonggi-do (KR); Jun Ho LEE, Icheon-si Gyeonggi-do (KR); Boo Ho JUNG, Icheon-si Gyeonggi-do (KR); Sun Ki CHO, Icheon-si Gyeonggi-do (KR); Yang Hee KIM, Icheon-si Gyeonggi-do (KR)

(73) Assignee: Hynix Semiconductor Inc., Icheon-si (KR)

(21) Appl. No.: 13/333,043

(22) Filed: Dec. 21, 2011

(30) Foreign Application Priority Data
Oct. 17, 2011 (KR) 10-2011-0105996

(51) Int. Cl. H03L 5/00

(52) U.S. Cl. 327/306

(57) ABSTRACT

An internal voltage generation method includes the steps of: setting first to third sections by using a reference voltage; determining to which section an internal voltage level corresponds, among the first to third sections; and generating the internal voltage by controlling a voltage pumping amount according to a section corresponding to the internal voltage level.

### CROSS-REFERENCES TO RELATED APPLICATION

The present application claims priority under 35 U.S.C. §119(a) to Korean application number 10-2011-0105996, filed on Oct. 17, 2011, in the Korean Intellectual Property Office, which is incorporated herein by reference in its entirety.

### BACKGROUND

1. Technical Field

The present invention relates generally to a semiconductor apparatus, and more particularly to an internal voltage generation circuit and method.

2. Related Art

A semiconductor apparatus includes a circuit for generating a variety of internal voltages VPP, VBB, and VCORE from an external voltage by a charge pumping method or down converting method, in order to perform a stable operation. The charge pumping method is used for generating a boosting voltage VPP or back bias voltage VBB, and the down converting method is used for generating a core voltage VCORE which is an internal voltage having a lower level than the external voltage.

FIG. 1A is a circuit diagram of a known internal voltage generation circuit based on the charge pumping method.

FIG. 1A illustrates an example of an internal voltage generation circuit which generates an internal voltage by controlling a plurality of pumps.

The internal voltage generation circuit includes an internal voltage detection unit 20, a pumping control signal generation unit 30, and a pump unit 40.

The internal voltage detection unit 20 is configured to activate a detection signal DET when the level of a fed-back internal voltage VINT is lower than the level of a reference voltage VREF which is a target level. The pumping control signal generation unit 30 is configured to generate an oscillating signal OSC at an oscillator 31, when the detection signal DET is activated. Furthermore, the pumping control signal generation unit 30 delays the oscillating signal OSC by one or more of clock cycle through first to third flip-flops 32_1 to 32_3, and generates first to third pumping control signals PU_CTRL1 to PU_CTRL3. The first to third pumping control signals PU_CTRL1 to PU_CTRL3 are used to control first to third pumps 41 to 43 of the pump unit 40, respectively.

In the known internal voltage generation circuit, the plurality of pumps are provided to generate the internal voltage, and the first pump 41 is driven at the initial state. However, when the internal voltage has not reached the target level after amplifying the internal voltage by the first pump 41, the second pump 42 is driven after a predetermined time passes. Furthermore, when the internal voltage has not reached the target level even after amplifying the internal voltage by the second pump 42, the third pump 43 is driven.

FIG. 1B is a waveform diagram of the known internal voltage generation circuit.

When the semiconductor apparatus consumes a current, the internal voltage VINT may drop below the reference voltage VREF. At this time, the detection signal DET is activated. At the initial stage of the charge pumping method, only the first pumping control signal PU_CTRL1 is activated. However, if the internal voltage VINT has not reached the target level, the second pumping control signal PU_CTRL2 is activated. Then, if the internal voltage VINT has not reached the target level even after amplifying the internal voltage by the first and second pump, the third pumping control signal PU_CTRL3 is activated. Accordingly, the internal voltage VINT reaches the reference voltage VREF, the detection signal DET is deactivated, and the pumping operation is stopped.

In the known internal voltage generation circuit which sequentially controls the plurality of pumps to generate the internal voltage, an amount of voltage to be pumped increases at each cycle of the clock signal. Therefore, as shown in FIG. 1B, the known internal voltage generation circuit may have a wide range of fluctuation of the pumping voltage (corresponding to a range A). This may degrade the voltage characteristic of the internal voltage generation circuit.

### SUMMARY

An internal voltage generation circuit and method capable of elaborately generating an internal voltage by controlling a plurality of pumps according to the level of a fed-back internal voltage is described herein.

In one embodiment of the present invention, an internal voltage generation method includes the steps of: setting first to third sections by using a reference voltage; determining to which section an internal voltage level corresponds, among the first to third sections; and generating the internal voltage by controlling a voltage pumping amount according to the section corresponding to the internal voltage level.

In another embodiment of the present invention, an internal voltage generation circuit includes: a sub voltage generation unit configured to divide a target level of an internal voltage by a predetermined interval and output first and second sub voltages; a is detection unit configured to compare the internal voltage with the first and second sub voltages and generate first and second detection signals according to the comparison results; a pumping control signal generation unit configured to generate first and second pumping control signals according to whether the first and second detection signals are activated or not; and a pump unit configured to receive the first and second pumping control signals and generate the internal voltage.

In another embodiment of the present invention, an internal voltage generation circuit includes: a sub voltage generation unit configured to generate a plurality of sub voltages from a reference voltage; a detection unit configured to receive an internal voltage, compare the internal voltage with the plurality of sub voltages, and generate a plurality of detection signals according to the comparison results; a pumping control signal generation unit configured to activate one or more pumping control signals among a plurality of pumping control signals, during a period where one or more of the corresponding detection signals are activated; and a pump unit configured to generate the internal voltage according to the plurality of pumping control signals.

### BRIEF DESCRIPTION OF THE DRAWINGS

Features, aspects, and embodiments are described in conjunction with the attached drawings, in which:

FIG. 1A is a circuit diagram of a known internal voltage generation circuit based on the charge pumping method;

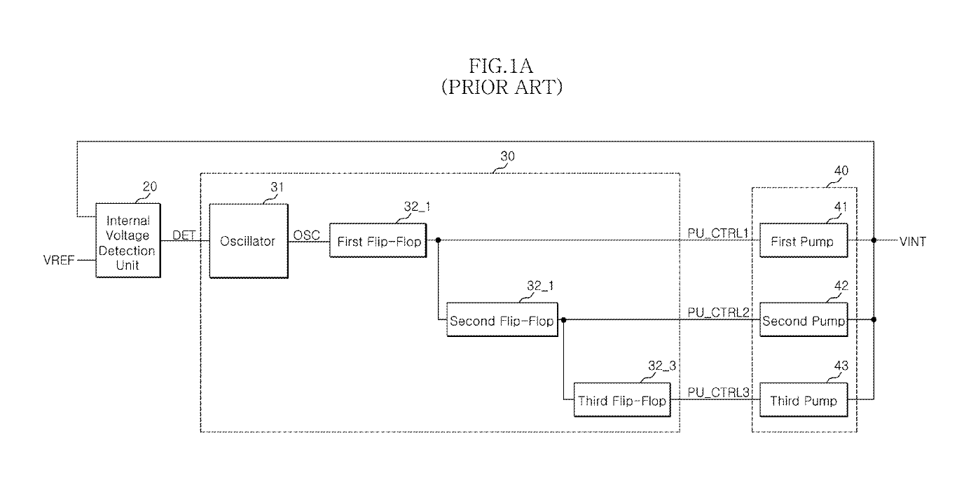

FIG. 1B is a waveform diagram of the known internal voltage generation circuit of FIG. 1A;

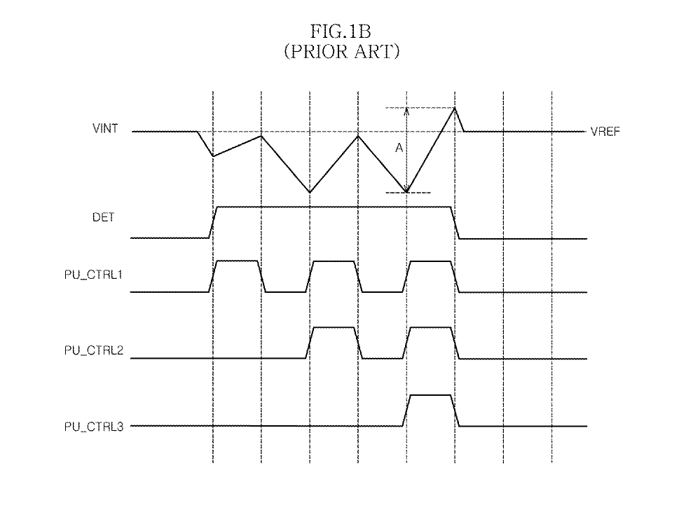

FIG. 2 is a circuit diagram of an internal voltage generation circuit according to an embodiment;

FIG. 3 is a circuit diagram illustrating a detailed configuration of the internal voltage generation circuit of FIG. 2; and

FIG. 4 is a waveform diagram explaining the operation of the internal voltage generation circuit according to an embodiment.

### DETAILED DESCRIPTION

Hereinafter, an internal voltage generation circuit and method according to the present invention will be described below with reference to the accompanying drawings through exemplary embodiments.

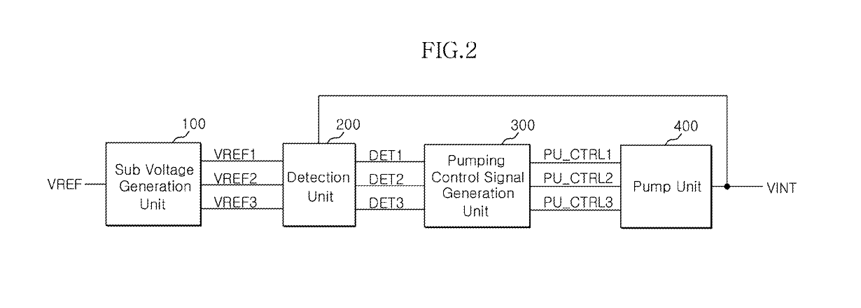

FIG. 2 is a circuit diagram of an internal voltage generation circuit according to an embodiment of the present invention.

The internal voltage generation circuit includes a sub voltage generation unit 100, a detection unit 200, a pumping control signal generation unit 300, and a pump unit 400.

The sub voltage generation unit 100 is configured to receive a reference voltage VREF, divide the reference voltage VREF, and output the divided voltages as first to third sub voltages VREF1 to VREF3. The reference voltage VREF corresponds to a target level of the internal voltage VINT generated by the internal voltage generation circuit according to an embodiment of the present invention. The reference voltage VREF may be applied from outside through a pad. Alternatively, the reference voltage VREF may be generated and supplied by an internal reference voltage generator.

The detection unit 200 is configured to receive the internal voltage VINT and compare the internal voltage VINT with the first to third sub voltages VREF1 to VREF3. Therefore, when the internal voltage VINT is lower than the first sub voltage VREF1, the detection unit 200 activates a first detection signal DET1. Similarly, when the internal voltage VINT is lower than the second sub voltage VREF2, the detection unit 200 activates a second detection signal DET2, and when the internal voltage VINT is lower than the third sub voltage VREF3, the detection unit 200 activates a third detection signal DET3.

The pumping control signal generation unit 300 is configured to receive the first to third detection signals DET1 to DET3 and generate first to third pumping control signals PU_CTRL1 to PU_CTRL3 corresponding to the first to third detection signals DET1 to DET3, respectively. Further, during a period where each of the first to third detection signals DET1 to DET3 is activated, a corresponding pumping control signal among first to third pumping control signals PU_CTRL1 to PU_CTRL3 is activated.

The pump unit 400 includes a plurality of pumps, and is configured to generate the internal voltage VINT according to the first to third pumping control signals PU_CTRL1 to PU_CTRL3. That is, a pump corresponding to an activated signal, among the first to third pumping control signals PU_CTRL1 to PU_CTRL3, is enabled to control a charge pump amount.

According to an embodiment of the present invention, the number of enabled pumps of the pump unit 400 is controlled according to the level of the internal voltage VINT. Therefore, the generation of the internal voltage VINT may be stably performed. The sub voltage generation unit 100 serves to divide the target level into minute sections, in order to determine the level of the internal voltage VINT. As the reference voltage VREF is divided into the first to third sub voltages VREF1 to VREF3, the target level may be divided into a section from the reference voltage VREF to the first sub voltage VREF1, a section from the first sub voltage VREF1 to the second sub voltage VREF2, and a section from the second sub voltage VREF2 to the third sub voltage VREF3. The detection unit 200 serves to determine to which section the internal voltage VINT corresponds among the sections, through the detection signals DET1 to DET3.

When the level of the internal voltage VINT corresponds to a section having a relatively low level, a plurality of pumps are simultaneously enabled to pump a large amount of charge. When the level of the internal voltage VINT corresponds to a section having a relatively high level, a smaller number of pumps are enabled to pump a relatively small amount of charge. Accordingly, it is possible to stably generate the internal voltage VINT with the target level.

In an embodiment of the present invention, the sub voltage generation unit 100 generates the first to third sub voltages VREF1 to VREF3 to divide the target level into three sections. However, the present invention is not limited thereto, and the number of sections may be controlled to a smaller or larger number.

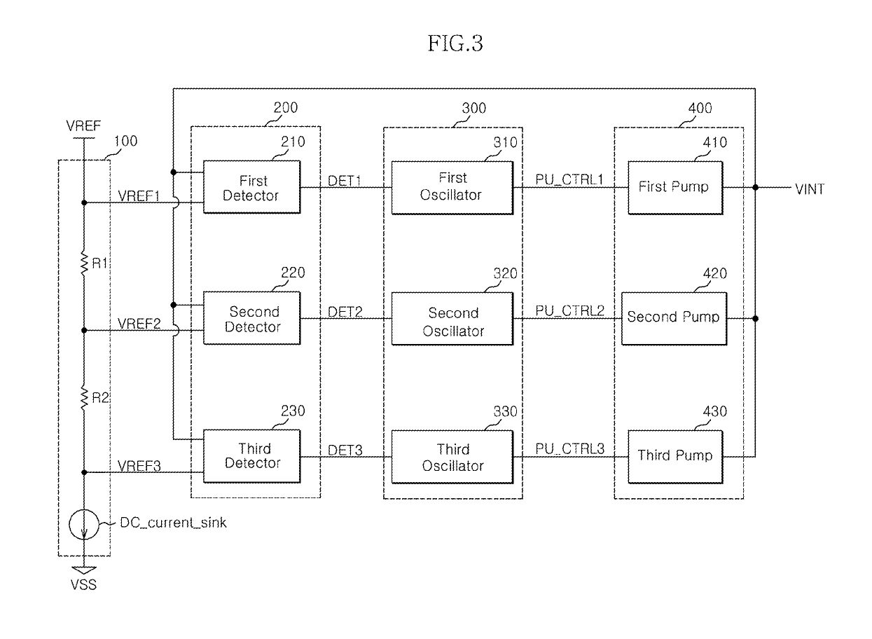

FIG. 3 is a circuit diagram illustrating a detailed configuration of the internal voltage generation circuit of FIG. 2.

The sub voltage generation unit 100 includes first and second resistors R1 and R2 and a constant current source DC_current_sink. The sub voltage generation unit 100 is configured to divide the level of the reference voltage VREF using the voltage division characteristic of the resistors. The first and second resistors R1 and R2 are coupled in series between the reference voltage terminal VREF and the constant current source DC_current_sink. Also, the sub voltage generation unit 100 outputs a voltage of a node between a terminal of the reference voltage VREF and the first resistors R1 as the first sub voltage VREF1, outputs a voltage of a node between the first and second resistors R1 and R2 as the second sub voltage VREF2, and outputs a voltage of a node between the second resistor R2 and the constant current source DC_current_sink as the third sub voltage VREF3.

The detection unit 200 includes first to third detectors 210 to 230. The first detector 210 is configured to compare the internal voltage VINT with the first sub voltage VREF1 and output the first detection signal DET1 which is activated when the level of the internal voltage VINT is lower than the level of the first sub voltage VREF1. The second detector 220 is configured to compare the internal voltage VINT with the second sub voltage VREF2 and output the second detection signal DET2 which is activated when the level of the internal voltage VINT is lower than the level of the second sub voltage VREF2. The third detector 230 is configured to compare the internal voltage VINT with the third sub voltage VREF3 and output the third detection signal DET3 which is activated when the level of the internal voltage VINT is lower than the level of the third sub voltage VREF3. The first to third detectors 210 to 230 may include a comparator, that is, an operational amplifier (OP-AMP).

The pumping control signal generation unit 300 includes first to third oscillators 310 to 330. The first oscillator 310 is configured to generate the first pumping control signal PU_CTRL1 which is activated in a period where the first detection signal DET1 is activated. The second oscillator 320 is configured to generate the second pumping control signal PU_CTRL2 which is activated in a period where the second detection signal DET2 is activated. The third oscillator 330 is configured to generate the third pumping control signal PU_CTRL3 which is activated in a period where the third detection signal DET3 is activated. Since the detailed configuration of the first to third oscillators 310 to 330 is obvious to those skilled in the art, the detailed descriptions thereof are omitted herein.

The pump unit 400 includes first to third pumps 410 to 430. The first pump 410 is configured to generate the internal voltage by pumping charges when the first pumping control signal PU_CTRL1 is activated and inputted. The second pump 420 is configured to generate the internal voltage by pumping charges when the second pumping control signal PU_CTRL2 is activated and inputted. The third pump 430 is configured to generate the internal voltage by pumping charges when the third pumping control signal PU_CTRL3 is activated and inputted. When a large number of pumping control signals are activated at the same time, a large amount of charge is pumped, and thus the internal voltage is generated at high speed. When a small number of pumping control signals are activated, a small amount of charge is pumped, and thus the internal voltage is generated at low speed. Since the detailed configuration of the first to third pumps 410 to 430 is obvious to those skilled in the art, the detailed descriptions thereof are omitted herein.

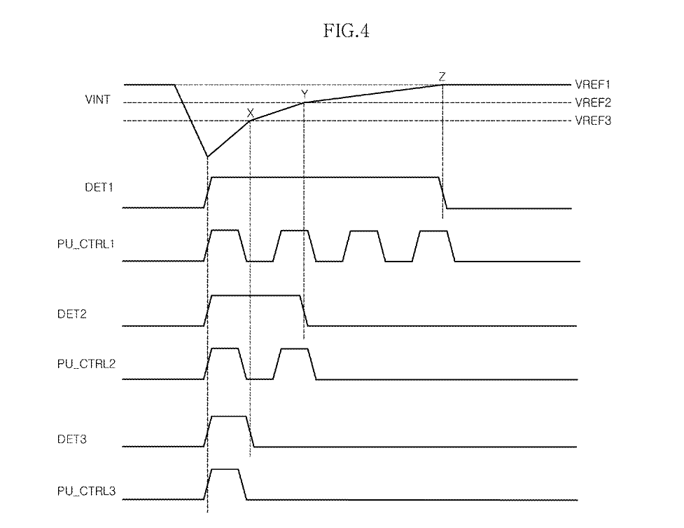

FIG. 4 is a waveform diagram explaining the operation of the internal voltage generation circuit according to an embodiment of the present invention.

When the semiconductor apparatus is operated to consume a current, the level of an internal voltage may drop. Referring to FIG. 4, since the level of the internal voltage VINT drops below the level of the third sub voltage VREF3, all of the first to third detection signals DET1 to DET3 are activated during a period from the initial time point to a time point X. Therefore, since all of the first to third pumping control signals DET1 to DET3 are activated during this period, the internal voltage VINT is generated at high speed.

Then, when the level of the internal voltage VINT is higher than the third sub voltage VREF3 but lower than the second sub voltage VREF2, that is, during a period from the time point X to a time point Y, only the first and second detection signals DET1 and DET2 are activated. Therefore, since only the first and second pumping control signals PU_CTRL1 and PU_CTRL2 are activated during this period, the internal voltage is generated at lower speed than when all of the first to third pumping control signals PU_CTRL1 to PU_CTRL3 are activated.

Then, when the level of the internal voltage VINT is higher than the second sub voltage VREF2 but lower than the first sub voltage VREF1, that is, during a period from the time point Y to a time point Z, only the first detection signal DET1 is activated. Therefore, since only the first pumping control signal PU_CTRL1 is activated during this period, the internal voltage VINT is generated at lower speed than when the first and second pumping control signals PU_CTRL1 and PU_CTRL2 are activated.

The internal voltage generation circuit according to an embodiment of the present invention includes the plurality of pumps to control the plurality of pumping operations according to the level of the internal voltage. The internal voltage generation circuit may detect the level of the internal voltage and control the pumping amount, thereby stably generating the internal voltage with a desired target level.

While certain embodiments have been described above, it will be understood to those skilled in the art that the embodiments described are by way of example only. Accordingly, the internal voltage generation circuit described herein should not be limited based on the described embodiments. Rather, the internal voltage generation circuit described herein should only be limited in light of the claims that follow when taken in conjunction with the above description and accompanying drawings.

What is claimed is:

1. An internal voltage generation method comprising the steps of:
setting first to third sections by using a reference voltage;
determining to which section an internal voltage level corresponds, among the first to third sections; and
generating the internal voltage by controlling a voltage pumping amount according to the section corresponding to the internal voltage level.

2. The internal voltage generation method according to claim 1, wherein setting first to third sections by using the reference voltage comprises dividing the level of the reference voltage by a predetermined interval using a plurality of resistors, and generates a plurality of sub voltages.

3. The internal voltage generation method according to claim 1, wherein the voltage level of the first section is higher than the voltage level of the second section, and the voltage level of the second section is higher than the voltage level of the third section.

4. The internal voltage generation method according to claim 3, wherein determining to which section the internal voltage level corresponds comprises generating a detection signal by determining to which section the internal voltage level corresponds, and
wherein generating the internal voltage comprises controlling the voltage pumping amount in response to the detection signal.

5. The internal voltage generation method according to claim 4, wherein the detection signal comprises first to third detection signals, and
wherein determining to which section the internal voltage level corresponds comprises activating the first detection signal when the internal voltage level corresponds to the first section, activating the first and second detection signals when the internal voltage level corresponds to the second section, and activating the first to third signals when the internal voltage level corresponds to the third section.

6. The internal voltage generation method according to claim 5, wherein generating the internal voltage comprises:
enabling a first pump when the first detection signal is activated, enabling a second pump when the second detection signal is activated, and enabling a third pump when the third detection signal is activated.

7. An internal voltage generation circuit comprising:
a sub voltage generation unit configured to divide a target level of an internal voltage by a predetermined interval and output first and second sub voltages;
a detection unit configured to compare the internal voltage with the first and second sub voltages and generate first and second detection signals according to the comparison results;
a pumping control signal generation unit configured to generate first and second pumping control signals according to whether the first and second detection signals are activated or not; and
a pump unit configured to receive the first and second pumping control signals and generate the internal voltage.

8. The internal voltage generation circuit according to claim 7, wherein the first sub voltage is higher than the second sub voltage.

9. The internal voltage generation circuit according to claim 8, wherein the detection unit comprises:
a first detector configured to activate the first detection signal when the internal voltage level is lower than the first sub voltage; and
a second detector configured to activate the second detection signal when the internal voltage level is lower than the second sub voltage.

10. The internal voltage generation circuit according to claim 8, wherein the pumping control signal generation unit comprises:
a first oscillator configured to generate the first pumping control signal by performing an oscillating operation during a period where the first detection signal is activated; and
a second oscillator configured to generate the second pumping control signal by performing an oscillating operation during a period where the second detection signal is activated.

11. An internal voltage generation circuit comprising:
a sub voltage generation unit configured to generate a plurality of sub voltages from a reference voltage;
a detection unit configured to receive an internal voltage, compare the internal voltage with the plurality of sub voltages, and generate a plurality of detection signals according to the comparison results;
a pumping control signal generation unit configured to activate one or more pumping control signals among a plurality of pumping control signals, during a period where one or more of the corresponding detection signals are activated; and
a pump unit configured to generate the internal voltage according to the plurality of pumping control signals.

12. The internal voltage generation circuit according to claim 11, wherein the sub voltage generation unit divides the reference voltage level by a predetermined interval using a plurality of divider resistors, and generates the plurality of sub voltages.

13. The internal voltage generation circuit according to claim 11, wherein, when the level of the internal voltage is lower than the compared sub voltage level, the detection unit activates the corresponding detection signal.

14. The internal voltage generation circuit according to claim 11, wherein the internal voltage comprises a boosting voltage.

15. The internal voltage generation circuit according to claim 11, wherein the internal voltage comprises a back bias voltage.
